(19) United States
(12) Patent Application Publication
(10) Pub. No.: US 2025/0126782 A1
(43) Pub. Date: Apr. 17, 2025

(54) SEMICONDUCTOR DEVICE AND METHOD FOR FABRICATING THE SAME

(71) Applicant: SK hynix Inc., Gyeonggi-do (KR)

(72) Inventors: Do Young JANG, Gyeonggi-do (KR); Jae Il KANG, Gyeonggi-do (KR); Myung Hee NA, Gyeonggi-do (KR)

(21) Appl. No.: 18/656,613

(22) Filed: May 7, 2024

(30) Foreign Application Priority Data
Oct. 17, 2023 (KR) 10-2023-0138532

(51) Int. Cl. H10B 41/41; H10B 41/30; H10B 43/30; H10B 43/40

(52) U.S. Cl. CPC H10B 41/41; H10B 41/30; H10B 43/30; H10B 43/40

(57) ABSTRACT

A semiconductor device and a method for fabricating the same are provided. The semiconductor device includes a first semiconductor structure including a cell region and a peripheral circuit region, and including a cell capacitor disposed in the cell region and a first insulating layer disposed in the cell region and the peripheral circuit region to cover the cell capacitor; a second semiconductor structure including a cell transistor disposed over the first insulating layer in the cell region and a peripheral circuit transistor disposed over the first insulating layer in the peripheral circuit region; and a first conductor passing through the first insulating layer to electrically connect a first cell source/drain region of the cell transistor and an electrode of the cell capacitor.

### CROSS-REFERENCE TO RELATED APPLICATION

This application claims priority under 35 U.S.C. § 119 to Korean Patent Application No. 10-2023-0138532 filed on Oct. 17, 2023, which is incorporated herein by reference in its entirety.

### BACKGROUND

### 1. Technical Field

Embodiments of the present disclosure relate to a semiconductor technology, and more particularly, to a semiconductor device including a selector and a transistor, and a method for fabricating the same.

### 2. Related Art

With the development of the electronics industry, electronic products are becoming increasingly smaller, higher-performance, and more highly integrated, while the operating speed of electronic products is required to increase.

In order to meet these demands, there is a need to develop technology that can maintain and/or improve the characteristics of unit elements that make up electronic products, such as transistors and capacitors, while reducing the area occupied by them.

### SUMMARY

In an embodiment of the present disclosure, a semiconductor device may include: a first semiconductor structure including a cell region and a peripheral circuit region, a cell capacitor disposed in the cell region, and a first insulating layer disposed in the cell region and the peripheral circuit region to cover the cell capacitor; a second semiconductor structure including a cell transistor disposed over the first insulating layer in the cell region and a peripheral circuit transistor disposed over the first insulating layer in the peripheral circuit region; and a first conductor passing through the first insulating layer to electrically connect a first cell source/drain region of the cell transistor and an electrode of the cell capacitor.

In an embodiment of the present disclosure, a method for fabricating a semiconductor device may include providing a first semiconductor structure that includes a cell region and a peripheral circuit region, a cell capacitor disposed in the cell region, and a first insulating layer disposed in the cell region and the peripheral circuit region to cover the cell capacitor; bonding a semiconductor substrate to an upper surface of the first insulating layer; forming a cell transistor in the cell region and forming a peripheral circuit transistor in the peripheral circuit region, using the semiconductor substrate; and forming a conductor that passes through the first insulating layer and connects a first source/drain region of the cell transistor with an electrode of the cell capacitor.

### BRIEF DESCRIPTION OF THE DRAWINGS

FIGS. 1 to 3 are cross-sectional views illustrating a semiconductor device and a method for fabricating the same, according to an embodiment of the present disclosure.

FIGS. 4 to 6 are cross-sectional views illustrating a semiconductor device and a method for fabricating the same, according to another embodiment of the present disclosure.

FIG. 7 is a cross-sectional view illustrating a semiconductor device and a method for fabricating the same, according to another embodiment of the present disclosure.

FIGS. 8 to 11 are cross-sectional views illustrating a semiconductor device and a method for fabricating the same, according to another embodiment of the present disclosure.

FIG. 12 is an enlarged perspective view of the portion P1 of FIG. 9.

FIG. 13 is a cross-sectional view illustrating a semiconductor device and a method for fabricating the same, according to another embodiment of the present disclosure.

### DETAILED DESCRIPTION

Hereinafter, various embodiments of the present disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

In the following description, a semiconductor structure may mean a semiconductor wafer, a semiconductor chip, etc., including a circuit and/or wiring structure that performs a predetermined function. Additionally, a semiconductor device may include two or more semiconductor structures that are stacked in a vertical direction and electrically and/or physically connected to each other. Hereinafter, it will be described in more detail with reference to the drawings.

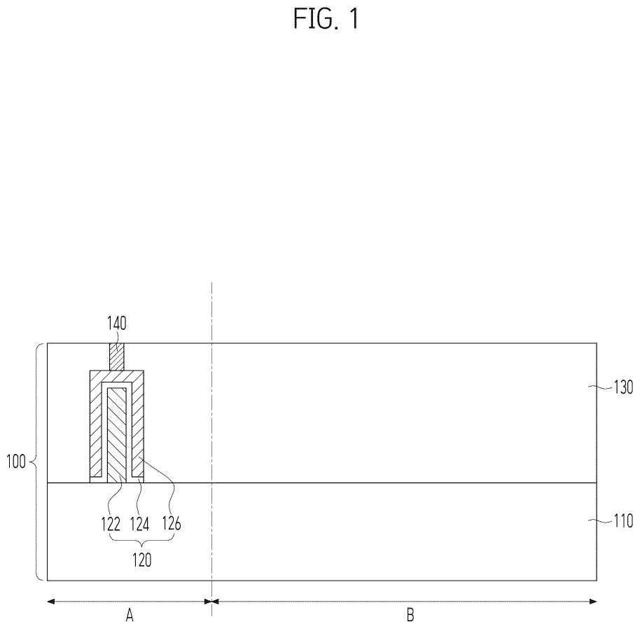

FIGS. 1 to 3 are cross-sectional views illustrating a semiconductor device and a method for fabricating the same, according to an embodiment of the present disclosure.

First, the fabricating method will be described.

Referring to FIG. 1, a first semiconductor structure 100 including a cell region A and a peripheral region B may be provided. The cell region A and the peripheral circuit region B may be adjacent to each other. Alternatively, the cell region A and the peripheral circuit region B may be spaced apart from each other. The cell region A may correspond to an area where a cell capacitor 120 of the first semiconductor structure 100 is disposed and a cell transistor of a second semiconductor structure, which will be described later, is to be disposed. The peripheral circuit region B may be arranged around the cell region A, and may correspond to an area where a peripheral circuit transistor of the second semiconductor structure, which will be described later, is to be disposed.

The first semiconductor structure 100 may include a first semiconductor substrate 110, a cell capacitor 120 formed over the first semiconductor substrate 110 in the cell region A, and a first insulating layer 130 formed over the first semiconductor substrate 110 of the cell region A and the peripheral circuit region B to cover the cell capacitor 120.

The cell capacitor 120 may include a first electrode 122, a second electrode 126, and a dielectric layer 124 interposed between the first electrode 122 and the second electrode 126. Each of the first electrode 122 and the second electrode 126 may include a conductive material, for example, a metal such as platinum (Pt), tungsten (W), aluminum (Al), copper (Cu), tantalum (Ta), titanium (Ti), ruthenium (Ru), or molybdenum (Mo), a compound of this metal, or an alloy of this metal. One of the first electrode 122 and the second electrode 126 may correspond to a storage electrode, and the other of the first electrode 122 and the second electrode 126 may correspond to a plate electrode. The dielectric layer 124 may include a dielectric material, such as silicon oxide or a high dielectric constant material with a higher dielectric constant than silicon oxide.

In the cell capacitor 120 of an embodiment, the first electrode 122 may have a pillar shape. The second electrode 126 may have a pillar shape surrounding the upper surface and the sidewall of the first electrode 122. An “upper surface” of an element as this term is used in this disclosure may refer to a “top surface” of the element. The dielectric layer 124 may be interposed between the first electrode 122 and the second electrode 126. For example, the dielectric layer 124 may have a shape that surrounds the upper surface and the sidewall of the first electrode 122 and extends below the lower surface of the second electrode 126. A “lower surface” of an element as this term is used in this disclosure may refer to a “bottom surface” of the element. That is, the cell capacitor 120 may correspond to a pillar-type capacitor. The pillar-type cell capacitor 120 may be formed by forming a pillar-shaped first electrode 122 by depositing a conductive material over the first semiconductor substrate 110 and patterning the conductive material, conformally depositing a dielectric material over the entire surface of the first semiconductor substrate 110 in which the first electrode 122 is formed, depositing a conductive material with a thickness sufficiently covering the first electrode 122 over the deposited dielectric material, and selectively etching the conductive material and the dielectric material to form the second electrode 126 and the dielectric layer 124. However, the embodiments of the present disclosure are not limited to this, and as long as the cell capacitor 120 includes a dielectric layer interposed between the two electrodes, the structure or shape of the cell capacitor 120 may be modified in various ways. For example, in another embodiment, an insulating material may be deposited over the first semiconductor substrate 110, a hole may be formed in the insulating material by etching the insulating material. A first electrode, a dielectric layer, and a second electrode may be sequentially buried in the hole to form a trench-type cell capacitor. In another embodiment, a conductive material, a dielectric material, and a conductive material may be sequentially deposited over the first semiconductor substrate 110, and these materials may be selectively etched to form a planar type of cell capacitor.

The first semiconductor substrate 110 may include a semiconductor material such as silicon or silicon germanium. In some embodiments, a lower structure (not shown) may be formed in the first semiconductor substrate 110. For example, a conductive structure electrically connected to the first electrode 122 of the cell capacitor 120, for example, a plate electrode, to apply a predetermined voltage to the first electrode 122 may be formed in the first semiconductor substrate 110.

The first insulating layer 130 may include various insulating materials, such as silicon oxide, silicon nitride, silicon oxynitride, or a combination thereof. The first insulating layer 130 may be formed, for example, through a deposition process of an insulating material. In some embodiments, a planarization process, such as a chemical mechanical polishing (CMP) process, may be also performed on the deposited insulating material. The first insulating layer 130 may have a planarized upper surface that is substantially parallel to the upper surface of the first semiconductor substrate 110.

In the first insulating layer 130, a first conductor 140 may be formed to pass through the first insulating layer 130 and be electrically connected to the second electrode 126, for example, the storage electrode, of the cell capacitor 120. The first conductor 140 may include a conductive material, for example, a metal such as platinum (Pt), tungsten (W), aluminum (AI), copper (Cu), tantalum (Ta), titanium (Ti), ruthenium (Ru), or molybdenum (Mo), a compound of this metal, or an alloy of this metal. In an embodiment, the first conductor 140 may have a contact plug shape, that is, a pillar shape, and may be disposed over the second electrode 126 to be in contact with the uppermost surface of the second electrode 126. The first conductor 140 may be formed by selectively etching the first insulating layer 130 to form a hole exposing the uppermost surface of the second electrode 126, depositing a conductive material to fill the hole over the first insulating layer 130, and performing a planarization process to expose the upper surface of the first insulating layer 130. However, the embodiments of the present disclosure are not limited to this, and as long as the first conductor 140 is electrically connected to the second electrode 126, the location, shape, and forming method of the first conductor 140 may be modified in various ways. For example, the first conductor 140 may include one or more contact plugs, one or more pads, or a combination thereof.

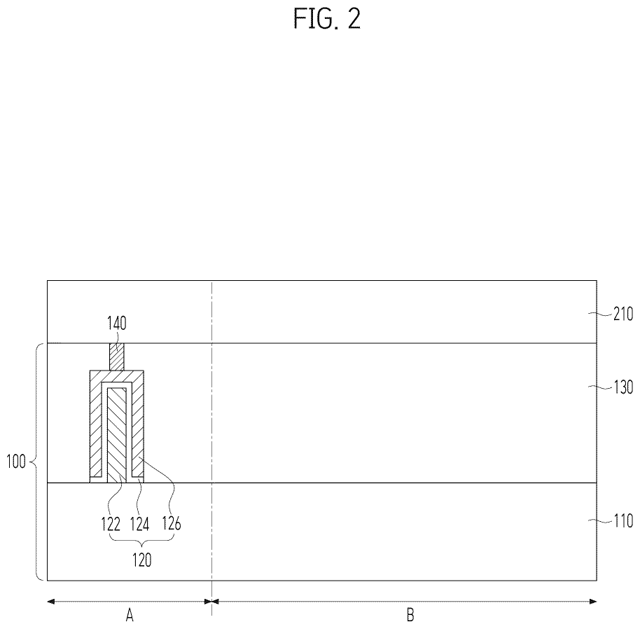

Referring to FIG. 2, a second semiconductor substrate 210 may be formed over the first semiconductor structure 100.

The second semiconductor substrate 210 may include a semiconductor material such as silicon or silicon germanium. The second semiconductor substrate 210 may have a flat plate shape that covers both the cell region A and the peripheral circuit region B. Accordingly, it may be said that the second semiconductor substrate 210 also includes the cell region A and the peripheral circuit region B. The second semiconductor substrate 210 may be bonded on the upper surface of the first insulating layer 130 of the first semiconductor structure 100. Hence, the second semiconductor substrate 210 may contact the upper surface of the first insulating layer 130. For example, the second semiconductor substrate 210 may correspond to a bare wafer.

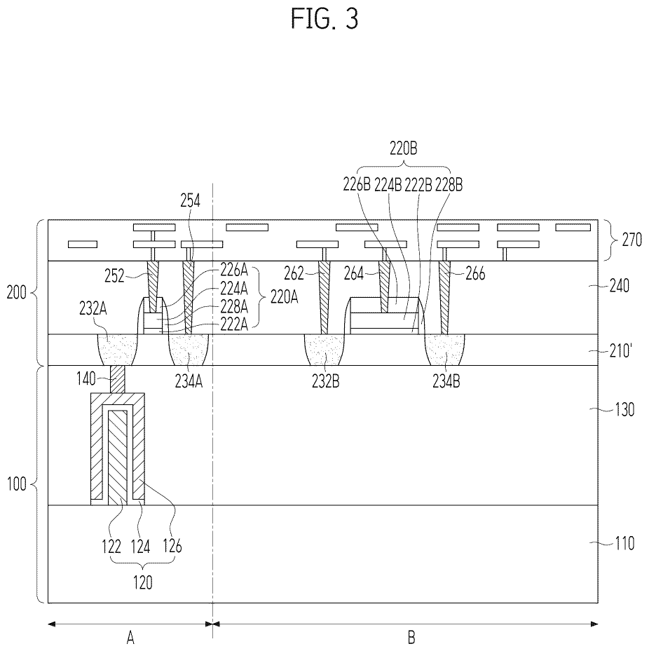

Referring to FIG. 3, the second semiconductor substrate 210 may undergo several processes to form a processed second semiconductor substrate 210′. The several processes may include at least one of a process of cutting the second semiconductor substrate 210 to a desired shape, a process of thinning the second semiconductor substrate 210 to a desired thickness, a cleaning process, or the like. This processing may be performed, if necessary, for example, when the second semiconductor substrate 210 is a bare wafer. In an embodiment, the second semiconductor substrate 210′ may have a reduced thickness compared to that of the second semiconductor substrate 210 through a thinning process. However, the processing of the second semiconductor substrate 210 is optional and may be omitted, so in some embodiments, the second semiconductor substrate 210 and the second semiconductor substrate 210′ may be the same or substantially the same.

Subsequently, a cell transistor and a peripheral circuit transistor may be formed. The cell transistor may include a cell gate pattern 220A formed over the second semiconductor substrate 210′ in the cell region A, and a first cell source/drain region 232A and a second cell source/drain region 234A formed in the second semiconductor substrate 210′ at both sides of the cell gate pattern 220A, respectively. The peripheral circuit transistor may include a peripheral gate pattern 220B formed over the second semiconductor substrate 210′ in the peripheral circuit region B, and first peripheral source/drain region 232B and a second peripheral source/drain region 234B formed in the second semiconductor substrate 210′ at both sides of the peripheral gate pattern 220B, respectively.

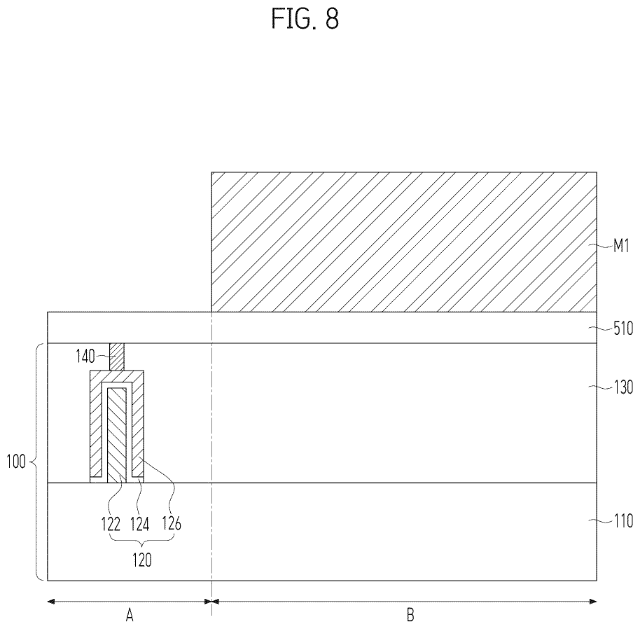

The cell gate pattern 220A may include a stacked structure of a gate insulating layer 222A, a gate electrode layer 224A, and a gate hard mask layer 226A, and a gate spacer 228A covering the sidewall of the stacked structure. The peripheral gate pattern 220B may include a stacked structure of a gate insulating layer 222B, a gate electrode layer 224B, and a gate hard mask layer 226B, and a gate spacer 228B on the sidewall of the stacked structure. The cell gate pattern 220A and the peripheral gate pattern 220B may be formed by sequentially depositing a gate insulating material, a gate electrode material, and a gate hard mask material over the second semiconductor substrate 210′, patterning the deposited materials, conformally depositing a gate spacer material over the patterned materials and the second semiconductor substrate 210′, and performing a blanket etching process on the gate spacer material to expose the upper surface of the second semiconductor substrate 210′. That is, the cell gate pattern 220A and the peripheral gate pattern 220B may be formed using the same process. However, the embodiments of the present disclosure are not limited thereto, and the cell gate pattern 220A and the peripheral gate pattern 220B may be formed using different processes. This will be described later with reference to FIGS. 8 to 13.

One of the first cell source/drain region 232A and the second cell source/drain region 234A may correspond to a source region, and the other of the first cell source/drain region 232A and the second cell source/drain region 234A may correspond to a drain region. One of the first peripheral source/drain region 232B and the second peripheral source/drain region 234B may correspond to a source region, and the other of the first peripheral source/drain region 232B and the second peripheral source/drain region 234B may correspond to a drain region. The first and second cell source/drain regions 232A and 234A and the first and second peripheral source/drain regions 232B and 234B may be formed by doping impurities into the second semiconductor substrate 210′ exposed by the cell gate pattern 220A and the peripheral gate pattern 220B. That is, the first and second cell source/drain regions 232A and 234A and the first and second peripheral source/drain regions 232B and 234B may be formed using the same process. However, the embodiments of the present disclosure are not limited thereto, and the first and second cell source/drain regions 232A and 234A and the first and second peripheral source/drain regions 232B and 234B may be formed using different processes. This will be described later with reference to FIGS. 8 to 13.

One of the first cell source/drain region 232A and the second cell source/drain region 234A, for example, the first cell source/drain region 232A, may be electrically connected to the second electrode 126 of the cell capacitor 120 through the first conductor 140. In an embodiment, the first cell source/drain region 232A may be formed at a position overlapping the first conductor 140 to a depth equal to the thickness of the second semiconductor substrate 210′, and thus, the lower surface of the first cell source/drain region 232A may be in direct contact with the first conductor 140. However, the embodiments of the present disclosure are not limited to this, and the depth or location of the first cell source/drain region 232A may be modified in various ways. When the lower surface of the first cell source/drain region 232A is not in direct contact with the first conductor 140, the first cell source/drain region 232A and the first conductor 140 may be electrically connected through another conductive component. The second cell source/drain region 234A and the first and second peripheral source/drain regions 232B and 234B may be formed to have substantially the same depth as the first cell source/drain region 232A, and accordingly, they may have a lower surface that contacts the upper surface of the first insulating layer 130. However, the embodiments of the present disclosure are not limited thereto, and the depths of the first and second cell source/drain regions 232A and 234A and the first and second peripheral source/drain regions 232B and 234B may be modified in various ways. When the depths of the first cell source/drain region 232A and the second cell source/drain region 234A are the same as the thickness of the second semiconductor substrate 210′, the channel of the cell transistor may be surrounded by the first cell source/drain region 232A, the second cell source/drain region 234A, and the first insulating layer 130. Accordingly, the cell transistor may have the same/similar effect as a transistor formed on an SOI (Silicon on Insulator) substrate, for example, a leakage current prevention effect. Similarly, when the depths of the first peripheral source/drain region 232B and the second peripheral source/drain region 234B are the same as the thickness of the second semiconductor substrate 210′, the channel of the peripheral circuit transistor may be surrounded by the first peripheral source/drain region 232B, the second peripheral source/drain region 234B, and the first insulating layer 130, and thus, a leakage current prevention effect may occur.

Subsequently, a second insulating layer 240 covering the cell gate pattern 220A and the peripheral gate pattern 220B may be formed over the second semiconductor substrate 210′ in the cell region A and the peripheral circuit region B. Then, second to sixth conductors 252, 254, 262, 264, and 266 may be formed to pass through the second insulating layer 240 and be connected to the gate electrode layer 224A of the cell gate pattern 220A, the second cell source/drain region 234A, the first peripheral source/drain region 232B, the gate electrode layer 224B of the peripheral gate pattern 220B, and the second peripheral source/drain region 234B, respectively. For example, each of the second to sixth conductors 252, 254, 262, 264, and 266 may have a contact plug shape.

Subsequently, a wiring layer 270 may be formed over the second insulating layer 240. The wiring layer 270 may include conductive structures of various shapes and layers so that it is electrically connected to the second to sixth conductors 252, 254, 262, 264, and 266 and apply voltages to them. For example, the wiring layer 270 may include a contact plug, a conductive line, or a combination thereof. The conductive structure in the wiring layer 270 is briefly shown as a box for convenience of description.

As a result, a semiconductor device in which the second semiconductor structure 200 is formed over the first semiconductor structure 100 may be fabricated.

Referring again to FIG. 3, the semiconductor device of an embodiment may include the first and second semiconductor structures 100, 200. The second semiconductor structure may be formed over the first semiconductor structure 100.

The first semiconductor structure 100 may include the first semiconductor substrate 110, the cell capacitor 120 formed over the first semiconductor substrate 110 in the cell region A, and the first insulating layer 130 formed over the first semiconductor substrate 110 in the cell region A and the peripheral circuit region B to cover the cell capacitor 120.

The second semiconductor structure 200 may include the second semiconductor substrate 210′, the cell transistor including the cell gate pattern 220A formed over the second semiconductor substrate 210′ in the cell region A and the first and second cell source/drain regions 232A and 234A formed in the second semiconductor substrate 210′ at both sides of the cell gate pattern 220A, the peripheral circuit transistor including the peripheral gate pattern 220B formed over the second semiconductor substrate 210′ in the peripheral circuit region B and the first and second peripheral source/drain regions 232B and 234B formed in the second semiconductor substrate 210′ at both sides of the peripheral gate pattern 220B, the second insulating layer 240 covering the cell gate pattern 220A and the peripheral gate pattern 220B over the semiconductor substrate 210′ of the cell region A and the peripheral circuit region B, and the wiring layer 270 disposed over the second insulating layer 240.

The second semiconductor substrate 210′ may be bonded to the upper surface of the first insulating layer 130, so the second semiconductor structure 200 may be physically connected to the first semiconductor structure 100.

The first cell source/drain region 232A of the cell transistor may be electrically connected to the second electrode 126 of the cell capacitor 120 through the first conductor 140 located below the cell transistor. Here, the depth of the first cell source/drain region 232A may be the same as the thickness of the second semiconductor substrate 210′, and accordingly, the first cell source/drain region 232A may have a lower surface that is in direct contact with the first conductor 140. The gate electrode layer 224A of the cell gate pattern 220A and the second cell source/drain region 234A may be electrically connected to the wiring layer 270 through the second and third conductors 252 and 254 located thereover. The first peripheral source/drain region 232B, the gate electrode layer 224B of the peripheral gate pattern 220B, and the second peripheral source/drain region 234B may be electrically connected to the wiring layer 270 through the fourth to sixth conductors 262, 264, and 266 located thereover.

According to the semiconductor device and its fabricating method described above, the following effects may be obtained.

First, since the cell transistor and peripheral circuit transistor are formed after forming the cell capacitor 120, the high temperature heat treatment process used when forming the cell capacitor 120 may be prevented from adversely affecting the characteristics of the cell transistor and peripheral circuit transistor.

In addition, by adjusting the depth of the source/drain 232A and 234A of the cell transistor and/or the depth of the source/drain 232B and 234B of the peripheral circuit transistor, the same/similar effect as when the cell transistor and/or the peripheral circuit transistor are formed using an SOI substrate may be obtained.

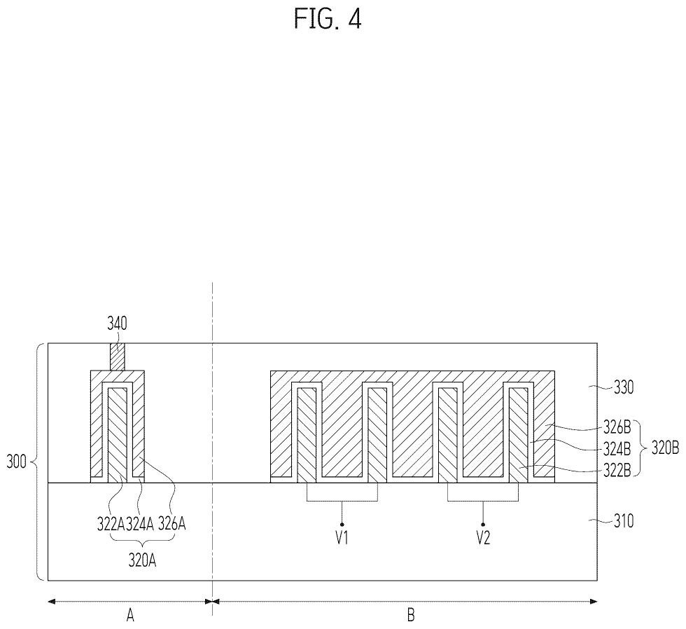

Additionally, in the peripheral circuit region B, the peripheral circuit transistor of the second semiconductor structure 200 may be electrically connected to the wiring layer 270 above it, and may not be electrically connected to the first semiconductor structure 100. That is, the space between the first semiconductor substrate 110 and the second semiconductor substrate 210′ in the peripheral circuit region B may be filled with the first insulating layer 130. Accordingly, by disposing various electrical components over the first semiconductor substrate 110 in the peripheral circuit region B, the area efficiency of the semiconductor device may be improved. For example, a decoupling capacitor may be disposed over the first semiconductor substrate 110 in the peripheral circuit region B, which will be described with reference to FIGS. 4 to 6.

FIGS. 4 to 6 are cross-sectional views illustrating a semiconductor device and a method for fabricating the same, according to another embodiment of the present disclosure. The description will focus on differences from the above-described embodiment.

First, the fabricating method will be described.

Referring to FIG. 4, a first semiconductor structure 300 including a cell region A and a peripheral region B may be provided. The first semiconductor structure 300 may include a first semiconductor substrate 310, a cell capacitor 320A formed over the first semiconductor substrate 310 in the cell region A, a decoupling capacitor 320B formed over the first semiconductor substrate 310 in the peripheral circuit region B, a first insulating layer 330 covering the cell capacitor 320A and the decoupling capacitor 320B over the first semiconductor substrate 310 of the cell region A and peripheral circuit region B.

The cell capacitor 320A may include a first electrode 322A, a second electrode 326A, and a dielectric layer 324A interposed between the first electrode 322A and the second electrode 326A.

The decoupling capacitor 320B may include a first electrode 322B, a second electrode 326B, and a dielectric layer 324B interposed between the first electrode 322B and the second electrode 326B. The decoupling capacitor 320B may function to reduce noise existing between operating power sources, such as a power supply voltage VDD, a ground voltage VSS, or the like.

The decoupling capacitor 320B of an embodiment may include a plurality of first electrodes 322B having a pillar shape, the second electrode 326B that overlaps the plurality of first electrodes 322B and surrounds the upper surfaces and the sidewalls of the first electrodes 322B, and the dielectric layer 324B interposed between the first electrodes 322B and the second electrode 326B. For example, the dielectric layer 324B may have a shape that surrounds the upper surfaces and the sidewalls of the plurality of first electrodes 322B and extends below the lower surface of the second electrode 326B. Each of the plurality of first electrodes 322B may correspond to a plate electrode, and the second electrode 326B may correspond to a storage electrode. Some of the plurality of first electrodes 322B may be electrically connected to a first power voltage V1, and others of the plurality of first electrodes 322B may be electrically connected to a second power voltage V2.

The cell capacitor 320A and the decoupling capacitor 320B may be formed using the same process. For example, the cell capacitor 320A and the decoupling capacitor 320B may be formed by forming the pillar-shaped first electrodes 322A and 322B by depositing a conductive material over the first semiconductor substrate 310 and patterning the conductive material, conformally depositing a dielectric material over the entire surface of the first semiconductor substrate 310 in which the first electrodes 322A and 322B are formed, depositing a conductive material with a thickness sufficiently covering the first electrodes 322A and 322B over the deposited dielectric material, and selectively etching the conductive material and the dielectric material to form the second electrodes 326A and 326B and the dielectric layers 324A and 324B. However, the embodiments of the present disclosure are not limited to this, and as long as each of the cell capacitor 320A and the decoupling capacitor 320B includes a dielectric layer interposed between two electrodes, the structure or shape of the cell capacitor 320A and the decoupling capacitor 320B may be modified in various ways. Even if the types of the cell capacitor 320A and the decoupling capacitor 320B are modified, the cell capacitor 320A and the decoupling capacitor 320B may be formed using the same process, and accordingly, process simplification may be possible.

A conductive structure may be formed in the first semiconductor substrate 310 to be electrically connected to the first electrode 322A of the cell capacitor 320A to apply a predetermined voltage to the first electrode 322A. In addition, conductive structures may be formed in the first semiconductor substrate 310 to be electrically connected to some of the plurality of first electrodes 322B of the decoupling capacitor 320B to apply the first power voltage V1 thereto and others of the plurality of first electrodes 320B of the decoupling capacitor 320B to apply the second power voltage V2 thereto.

A first conductor 340 may be formed in the first insulating layer 330 to pass through the first insulating layer 330 and electrically connect to the second electrode 326A of the cell capacitor 320A.

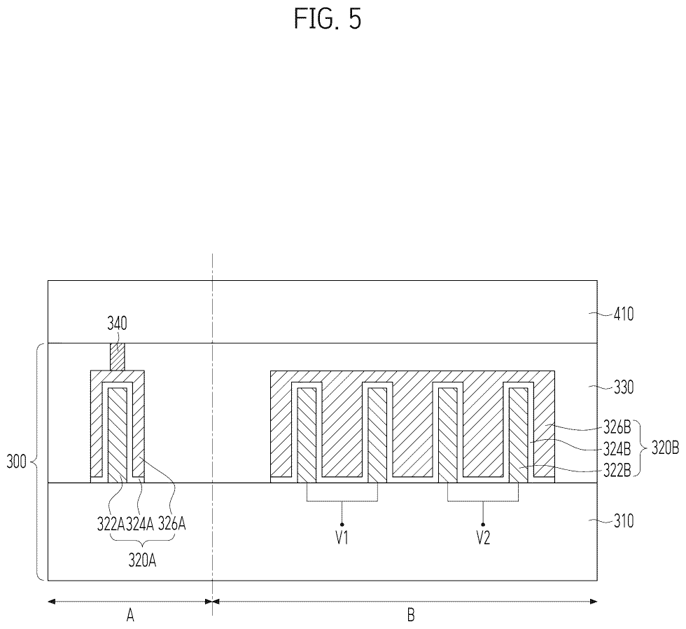

Referring to FIG. 5, a second semiconductor substrate 410 may be formed over the first semiconductor structure 300.

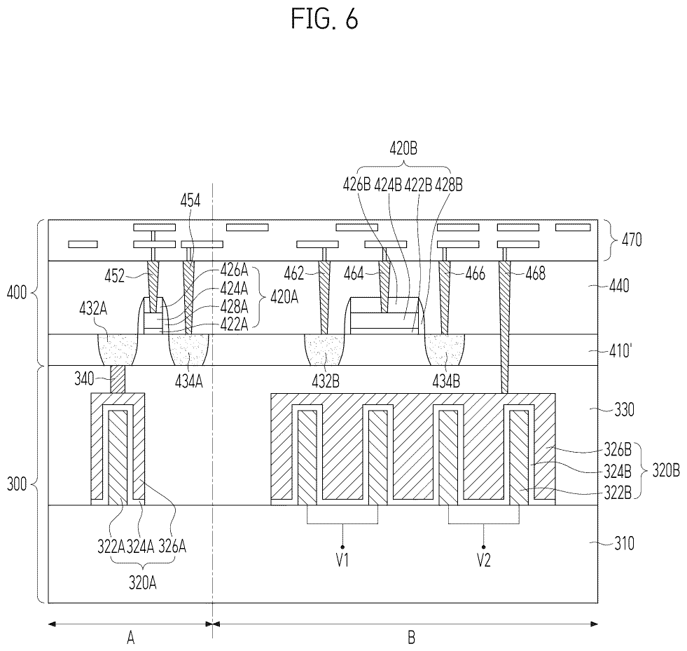

Referring to FIG. 6, the second semiconductor substrate 410 may be processed to form the processed second semiconductor substrate 410′.

Subsequently, a cell transistor including a cell gate pattern 420A formed over the second semiconductor substrate 410′ in the cell region A and a first cell source/drain region 432A and a second cell source/drain region 434A formed in the second semiconductor substrate 410′ at both sides of the cell gate pattern 420A, and a peripheral circuit transistor including a peripheral gate pattern 420B formed over the second semiconductor substrate 410′ in the peripheral circuit region B and a first peripheral source/drain region 432B and a second peripheral source/drain region 434B formed in the second semiconductor substrate 410′ at both sides of the peripheral gate pattern 420B, may be formed. The cell gate pattern 420A may include a stacked structure of a gate insulating layer 422A, a gate electrode layer 424A, and a gate hard mask layer 426A, and a gate spacer 428A formed over the sidewall of the stacked structure. The peripheral gate pattern 420B may include a stacked structure of a gate insulating layer 422B, a gate electrode layer 424B, and a gate hard mask layer 426B, and a gate spacer 428B formed over the sidewall of the stacked structure. The first cell source/drain region 432A may be electrically connected to the second electrode 326A of the cell capacitor 320A through the first conductor 340.

Subsequently, a second insulating layer 440 covering the cell gate pattern 420A and the peripheral gate pattern 420B may be formed over the second semiconductor substrate 410′ in the cell region A and the peripheral circuit region B. Then, second to sixth conductors 452, 454, 462, 464, and 466 that pass through the second insulating layer 440 and are electrically connected to the gate electrode layer 424A of the cell gate pattern 420A, the second cell source/drain region 434A, the first peripheral source/drain region 432B, the gate electrode layer 424B of the peripheral gate pattern 420B, and the second peripheral source/drain region 434B, respectively, may be formed. In addition, a seventh conductor 468 that passes through the second insulating layer 440, the second semiconductor substrate 410′, and the first insulating layer 330 and is electrically connected to the second electrode 326B of the decoupling capacitor 320B, may be formed. The seventh conductor 468 may have a pillar shape in contact with the uppermost surface of the second electrode 326B, and may be formed using the same process as the forming process of the second to sixth conductors 452, 454, 462, 464, and 466.

Subsequently, a wiring layer 470 may be formed over the second insulating layer 440. The wiring layer 470 may be electrically connected to the second to seventh conductors 452, 454, 462, 464, 466, and 468, and apply voltages to them. In particular, the wiring layer 470 may apply, for example, a ground voltage as a required voltage to the second electrode 326B of the decoupling capacitor 320B, through the seventh conductor 468.

As a result, a semiconductor device in which the second semiconductor structure 400 is formed over the first semiconductor structure 300 may be fabricated.

According to the semiconductor device and its fabricating method described above, the decoupling capacitor 320B may be formed over the first semiconductor substrate 310 in the peripheral circuit region B, during the process of forming the cell capacitor 320A. Therefore, the decoupling capacitor 320B may be obtained without increasing the process operations or increasing the area. As a result, the integration and the characteristics of the semiconductor device may be improved substantially.

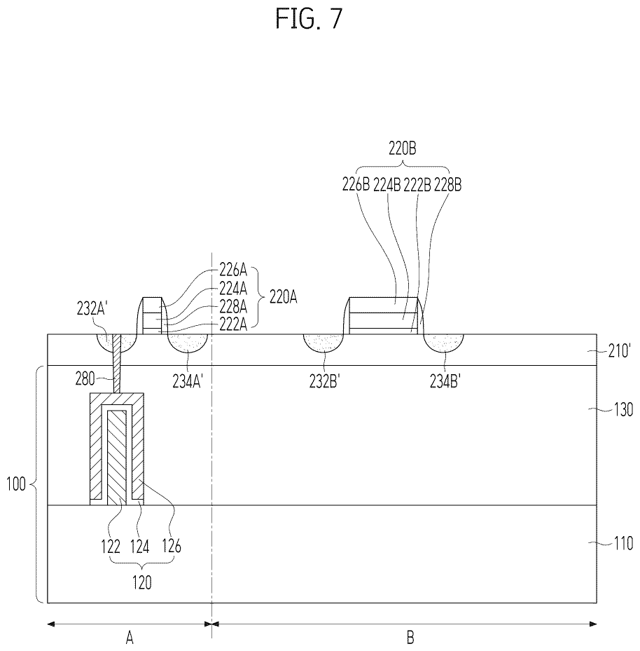

In the above-described embodiments, the first conductor is formed together in the process of forming the first semiconductor structure, but the embodiments of the present disclosure are not limited thereto. As long as the first conductor electrically connects the source/drain region of the cell transistor with the electrode of the cell capacitor, the order of the forming process of the first conductor or the shape of the first conductor may be modified in various ways. This will be described by way of example with reference to FIG. 7.

FIG. 7 is a cross-sectional view illustrating a semiconductor device and a method for fabricating the same, according to another embodiment of the present disclosure. The description will focus on the differences from the embodiment of FIGS. 1 to 3, and components that are substantially the same as those of the embodiment of FIGS. 1 to 3 will be denoted by the same reference numerals.

Referring to FIG. 7, a first semiconductor structure 100 including a cell region A and a peripheral region B may be provided. The first semiconductor structure 100 may include a first semiconductor substrate 110, a cell capacitor 120 formed over the first semiconductor substrate 110 in the cell region A and including a first electrode 122, a dielectric layer 124, and a second electrode 126, and a first insulating layer 130 covering the cell capacitor 120 and the first semiconductor substrate 110 in the cell region A and the peripheral circuit region B.

Subsequently, a second semiconductor substrate 210′ may be formed over the first semiconductor structure 100 and covering the first semiconductor structure 100.

Subsequently, a cell transistor including a cell gate pattern 220A formed over the second semiconductor substrate 210′ in the cell region A and a first cell source/drain region 232A′, and a second cell source/drain region 234A′ formed in the second semiconductor substrate 210′ at both sides of the cell gate pattern 220A, and a peripheral circuit transistor including a peripheral gate pattern 220B formed over the second semiconductor substrate 210′ in the peripheral circuit region B, and a first peripheral source/drain region 232B′ and a second peripheral source/drain region 234B′ formed in the second semiconductor substrate 210′ at both sides of the peripheral gate pattern 220B, may be formed. In an embodiment, the depth of the first source/drain region 232A′ may be smaller than the thickness of the second semiconductor substrate 210′. Furthermore, the depths of the second cell source/drain region 234A′ and the first and second peripheral source/drain regions 232B′ and 234B′ may be smaller than the thickness of the second semiconductor substrate 210′.

Subsequently, a first conductor 280 may be formed to overlap the first cell source/drain region 232A′ and pass through the second semiconductor substrate 210′ and the first insulating layer 130 to be electrically connected to the second electrode 126 of the cell capacitor 120. The first conductor 280 may be formed by selectively etching the second semiconductor substrate 210′ and the first insulating layer 130 to form a hole exposing the upper surface of the second electrode 126 of the cell capacitor 120, depositing a conductive material thick enough to fill the hole, and performing a planarization process to expose the upper surface of the second semiconductor substrate 210′. Accordingly, the upper surface of the first conductor 280 may be located at substantially the same height as the upper surface of the second semiconductor substrate 210′, and a portion of the sidewall of the first conductor 280 may contact the first cell source/drain region 232A′. For example, a portion of the sidewall of the first conductor 280 may be surrounded by the first cell source/drain region 232A′.

The subsequent process may be substantially the same as that described in the above-described embodiment.

According to the semiconductor device and its fabricating method described above, even if the depth of the first cell source/drain region 232A′ is smaller than the thickness of the second semiconductor substrate 210′, the first cell source/drain region 232A′ and the second electrode 126 of the cell capacitor 120 may be electrically connected with each other, using the first conductor 280 passing through the second semiconductor substrate 210′ and the first insulating layer 130.

In the above-described embodiments, the cell transistor and the peripheral circuit transistor are formed using the same process, so that the cell transistor and the peripheral circuit transistor of the same type, for example, the planar type, are formed. However, the embodiments of the present disclosure are not limited to this, and the cell transistor and peripheral circuit transistor may be formed separately using separate processes. In this case, it may be possible to form not only the same type but also different types of the cell transistor and the peripheral circuit transistor, and accordingly, it may be possible to implement a semiconductor device including a cell transistor and a peripheral circuit transistor with independently required characteristics. This will be described with reference to FIGS. 8 to 13.

FIGS. 8 to 11 are cross-sectional views illustrating a semiconductor device and a method for fabricating the same, according to another embodiment of the present disclosure.

Referring to FIG. 8, a first semiconductor structure 100 including a cell region A and a peripheral region B may be provided. The first semiconductor structure 100 may include a first semiconductor substrate 110, a cell capacitor 120 formed over the first semiconductor substrate 110 in the cell region A and including a first electrode 122, a dielectric layer 124, and a second electrode 126, and a first insulating layer 130 covering the cell capacitor 120 over the first semiconductor substrate 110 of the cell region A and the peripheral circuit region B.

Subsequently, a second semiconductor substrate 510 may be formed over the first semiconductor structure 100.

Subsequently, a first mask pattern M1 may cover the second semiconductor substrate 510 of the peripheral circuit region B. Accordingly, the second semiconductor substrate 510 of the cell region A may be exposed.

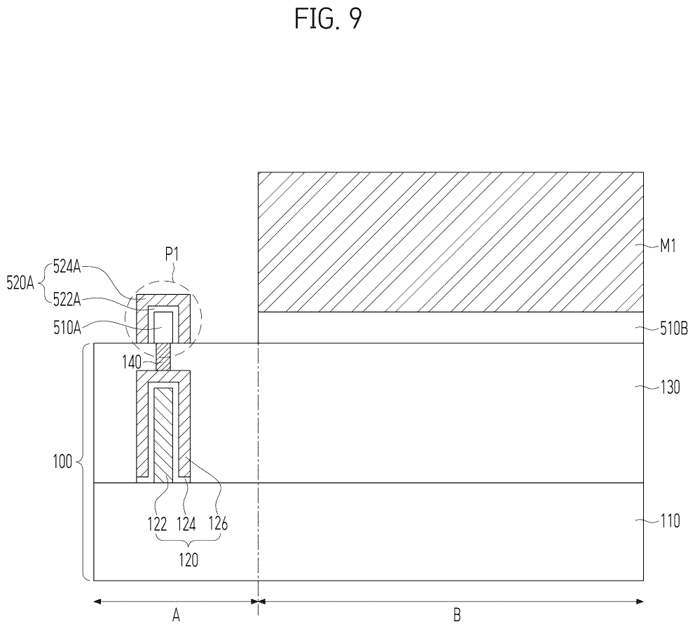

Referring to FIG. 9, the second semiconductor substrate 510 exposed by the first mask pattern M1 may be selectively etched to form a semiconductor fin 510A.

Subsequently, a gate insulating material and a gate electrode material may be deposited along the sidewall and the upper surface of the semiconductor fin 510A, and may be patterned to form a cell gate pattern 520A including a gate insulating layer 522A and a gate electrode layer 524A.

Subsequently, by doping impurities into the semiconductor fin 510A exposed by the cell gate pattern 520A to form source/drain regions, a FinFET structure may be formed. In this cross-sectional view, the source/drain regions are not indicated for convenience of description.

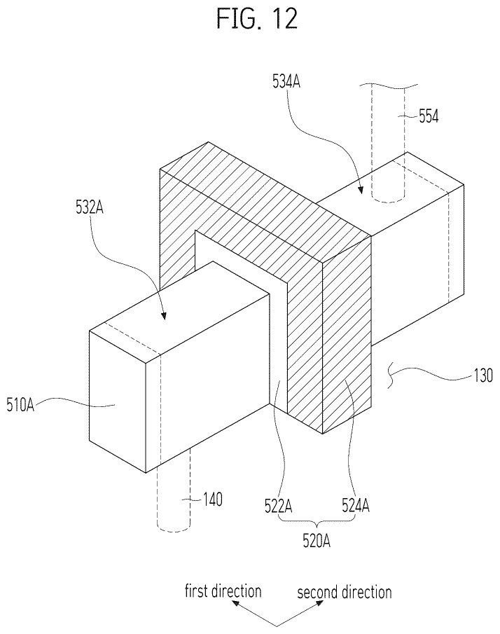

A P1 portion including the semiconductor fin 510A, the cell gate pattern 520A, and the source/drain regions will be described in more detail with reference to FIG. 12.

FIG. 12 is an enlarged perspective view of the portion P1 of FIG. 9. The portion P1 of FIG. 9 is a front view of the semiconductor fin 510A and the cell gate pattern 520A of FIG. 12, and may correspond to a cross-section along the first direction of FIG. 12.

Referring to FIG. 12, the semiconductor fin 510A may have a pillar shape where the width in the first direction is smaller than the width in the second direction. The cell gate pattern 520A may surround the sidewall and the upper surface of the semiconductor fin 510A while crossing the semiconductor fin 510A in the first direction. Accordingly, the semiconductor fin 510A may have portions that are exposed by the cell gate pattern 520A and are located at both sides of the cell gate pattern 520A in the second direction. The doping of impurities may be performed into the exposed portions of the semiconductor fin 510A, thereby forming the first cell source/drain region 532A and the second cell source/drain region 534A in the semiconductor fin 510A at both sides of the cell gate pattern 520A. For example, the depths of the first cell source/drain region 532A and the second cell source/drain region 534A may be substantially the same as the thickness of the semiconductor fin 510A.

The first cell source/drain region 532A may be electrically connected to the first conductor 140 located below it. For example, the lower surface of the first source/drain region 532A may directly contact the first conductor 140. Excluding a portion of the lower surface of the first source/drain region 532A, which is in contact with the first conductor 140, a remaining portion of the lower surface of the first source/drain region 532A may contact the upper surface of the first insulating layer 130. As will be described later, as an example, the second cell source/drain region 534A of the semiconductor fin 510A may be electrically connected to the third conductor 554 located above the second cell source/drain region 534A.

Referring again to FIG. 9, the portion of the second semiconductor substrate 510 that is covered by the first mask pattern M1 may be maintained as denoted by a reference numeral 510B.

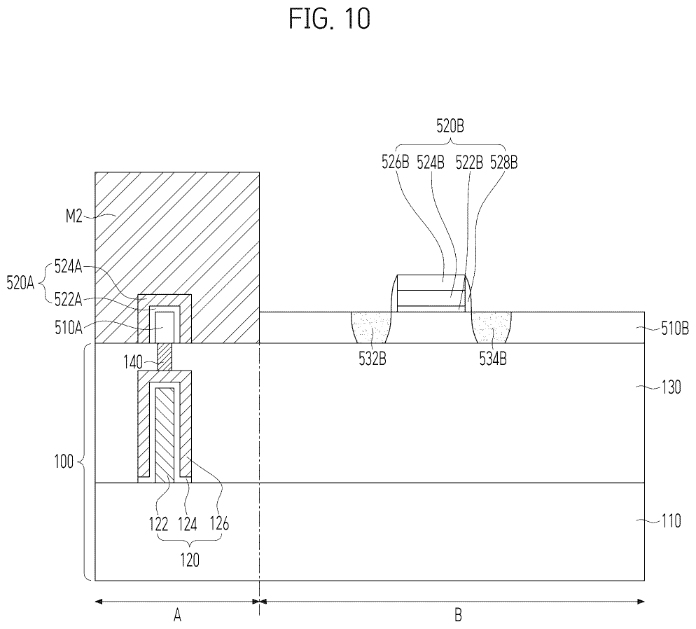

Referring to FIG. 10, after removing the first mask pattern M1, a second mask pattern M2 may be formed covering the cell gate pattern 520A and the first insulating layer 130 in the cell region A only. Accordingly, the second semiconductor substrate 510B in the peripheral circuit region B may be exposed.

Subsequently, a peripheral circuit transistor may be formed including a peripheral gate pattern 520B formed over the second semiconductor substrate 510B in the peripheral circuit region B. Furthermore, a first peripheral source/drain region 532B and a second peripheral source/drain region 534B may be formed at either side of the peripheral gate pattern 520B in the second semiconductor substrate 510B.

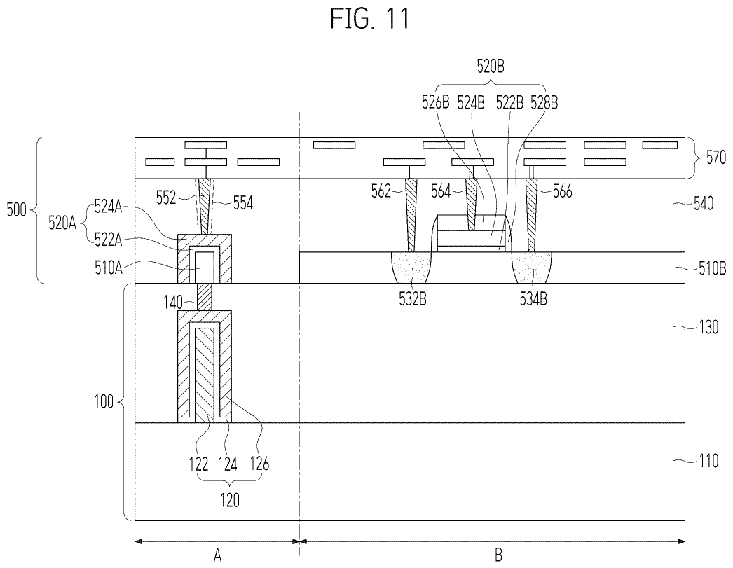

Referring to FIG. 11, after removing the second mask pattern M2, a second insulating layer 540 may cover the cell gate pattern 520A and the peripheral gate pattern 520B over the first insulating layer 130 of the cell region A and the second semiconductor substrate 510B of the peripheral circuit region B.

Subsequently, second to sixth conductors 552, 554, 562, 564, and 566 may be formed passing through the second insulating layer 540 and being respectively connected to the gate electrode layer 524A of the cell gate pattern 520A, the second cell source/drain region (see 534A in FIG. 12), the first peripheral source/drain region 532B, the gate electrode layer 524B of the peripheral gate pattern 520B, and the second peripheral source/drain region 534B.

Subsequently, a wiring layer 570 may be formed over the second insulating layer 540.

As a result, a semiconductor device in which the second semiconductor structure 500 is formed over the first semiconductor structure 100 may be fabricated.

According to the semiconductor device and its fabricating method described above, the cell transistor may be formed while the first mask pattern M1 covering the peripheral circuit region B is formed, and the peripheral circuit transistor may be formed while the second mask pattern M2 covering the cell region A is formed. Therefore, the cell transistor and the peripheral circuit transistor may be formed using different processes. As a result, it may be possible to independently form different types of the cell transistor and the peripheral circuit transistor. For example, as in an embodiment, it may be possible to implement a semiconductor device including a fin-type cell transistor and a planar-type peripheral circuit transistor. This semiconductor device may be applicable to a low-power device. In addition, in an embodiment, the peripheral circuit transistor is formed after forming the cell transistor, but the embodiments of the present disclosure are not limited thereto. In another embodiment, the peripheral circuit transistor may first be formed by covering the cell region A, and then, the cell transistor may be formed by covering the peripheral circuit region B.

In an embodiment, the case of forming a FinFET structure in the cell region A has been described, but the embodiments of the present disclosure are not limited to this. Transistors of various structures using the semiconductor fin 510A as a channel may be formed in the cell region A. For example, a transistor in which a gate electrode surrounds the sidewall of the semiconductor fin 510A and a gate insulating layer is interposed between the gate electrode and the semiconductor fin 510A, may be formed.

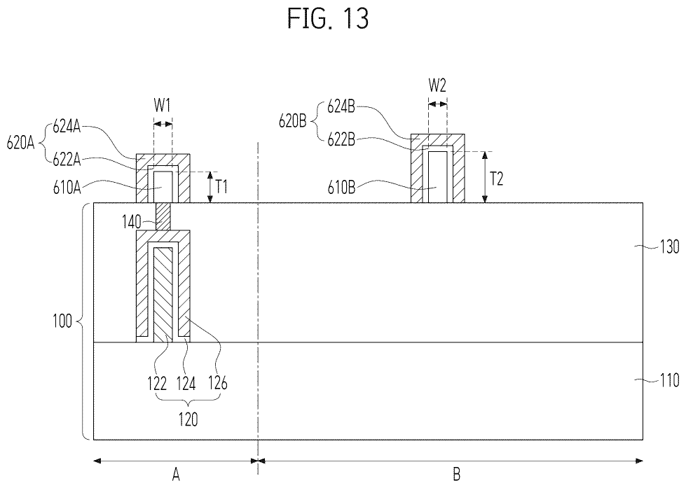

FIG. 13 is a cross-sectional view illustrating a semiconductor device and a method for fabricating the same, according to another embodiment of the present disclosure.

Referring to FIG. 13, a first semiconductor structure 100 including a cell region A and a peripheral region B may be provided. The first semiconductor structure 100 may include a first semiconductor substrate 110, a cell capacitor 120 formed over the first semiconductor substrate 110 in the cell region A and including a first electrode 122, a dielectric layer 124, and a second electrode 126, and a first insulating layer 130 covering the cell capacitor 120 over the first semiconductor substrate 110 of the cell region A and the peripheral circuit region B.

Subsequently, a fin-type cell transistor may be formed over the first semiconductor structure 100 in the cell region A, and a fin-type peripheral circuit transistor may be formed over the first semiconductor structure 100 in the peripheral circuit region B. The cell transistor may include a cell semiconductor fin 610A and a cell gate pattern 620A. The cell gate pattern 620A may include a gate insulating layer 622A and a gate electrode 624A. The peripheral circuit transistor may include a peripheral semiconductor fin 610B and a peripheral gate pattern 620B. The peripheral gate pattern 620B may include a gate insulating layer 622B and a gate electrode 624B.

Here, even if the cell transistor and the peripheral circuit transistor have the same pin type, their forming materials or shapes may be different. As described below, this may be because the cell transistor and the peripheral circuit transistor are formed independently. For example, at least one of the thickness T1 and the width W1 of the cell semiconductor fin 610A of the cell transistor may be different from at least one of the thickness T2 and the width W2 of the peripheral semiconductor fin 610B of the peripheral circuit transistor. The thicknesses T1 and T2 may also be referred to as heights. When the thickness T2 of the peripheral semiconductor fin 610B of the peripheral circuit transistor is greater than the thickness T1 of the cell semiconductor fin 610A of the cell transistor, a high-performance semiconductor device may be implemented.

Since the processes of forming the cell transistor and the peripheral circuit transistor are similar to those described in FIGS. 8 to 13, they will be briefly described below.

First, a second semiconductor substrate (not shown) may be formed over the first semiconductor structure 100, and then, the second semiconductor substrate in the cell region A may be selectively etched to form a cell semiconductor fin 610A while covering the peripheral circuit region B. Then, a cell gate pattern 620A may be formed over the cell semiconductor fin 610A, and source/drain regions may be formed by doping impurities, thereby forming a cell transistor. Although not shown, the depths of the source/drain regions may be the same as the thickness of the cell semiconductor fin 610A, similar to that described in FIG. 12.

Subsequently, the second semiconductor substrate in the peripheral circuit region B may be selectively etched to form a peripheral semiconductor fin 610B while covering the cell region A. Then, a peripheral gate pattern 620B may be formed over the peripheral semiconductor fin 610B, and source/drain regions may be formed by doping impurities, thereby forming a peripheral circuit transistor. Although not shown, the depths of the source/drain regions may be the same as the thickness of the peripheral semiconductor fin 610B, similar to that described in FIG. 12. At this time, in order to increase the thickness T2 of the peripheral semiconductor fin 610B than the thickness T1 of the cell semiconductor fin 610A, the thickness of the second semiconductor substrate in the peripheral circuit region B exposed by a mask pattern covering the cell region A may be increased. The peripheral semiconductor fin 610B may be formed by selectively etching the second semiconductor substrate with the increased thickness. Increasing the thickness of the second semiconductor substrate in the peripheral circuit region B may be possible by additionally forming a semiconductor material over the second semiconductor substrate through deposition, epitaxial growth, etc.

The subsequent process may be substantially the same as that described in FIG. 11.

According to the above embodiments of the present disclosure, it may be possible to improve the integration and the characteristics of semiconductor device.

Although various embodiments have been described for illustrative purposes, it will be apparent to those skilled in the art that various changes and modifications may be made without departing from the spirit and scope of the present teachings as defined in the following claims. Furthermore, the embodiments may be combined to form additional embodiments.

What is claimed is:

1. A semiconductor device comprising:
a first semiconductor structure including a cell region and a peripheral circuit region, a cell capacitor disposed in the cell region, and a first insulating layer disposed in the cell region and the peripheral circuit region to cover the cell capacitor;
a second semiconductor structure including a cell transistor disposed over the first insulating layer in the cell region and a peripheral circuit transistor disposed over the first insulating layer in the peripheral circuit region; and
a first conductor passing through the first insulating layer to electrically connect a first cell source/drain region of the cell transistor and an electrode of the cell capacitor.

2. The semiconductor device according to claim 1, wherein the second semiconductor structure includes a semiconductor substrate contacting an upper surface of the first insulating layer,
wherein the cell transistor includes a cell gate pattern disposed over the semiconductor substrate, and the first cell source/drain region and a second cell source/drain region formed in the semiconductor substrate at both sides of the cell gate pattern, respectively, and
wherein a depth of each of the first and second cell source/drain regions is equal to a thickness of the semiconductor substrate.

3. The semiconductor device according to claim 1, wherein the second semiconductor structure includes a semiconductor substrate contacting an upper surface of the first insulating layer,
wherein the peripheral circuit transistor includes a peripheral gate pattern disposed over the semiconductor substrate, and a first peripheral source/drain region and a second peripheral source/drain region formed in the semiconductor substrate at both sides of the peripheral gate pattern, respectively, and
wherein a depth of each of the first and second peripheral source/drain regions is equal to a thickness of the semiconductor substrate.

4. The semiconductor device according to claim 1, wherein the second semiconductor structure includes a cell semiconductor pin contacting an upper surface of the first insulating layer in the cell region,
wherein the cell transistor includes a cell gate pattern surrounding an upper surface and a sidewall of the cell semiconductor fin, and the first cell source/drain region and a second cell source/drain region formed in the cell semiconductor fin at both sides of the cell gate pattern, respectively, and
wherein a depth of each of the first and second cell source/drain regions is equal to a thickness of the cell semiconductor fin.

5. The semiconductor device according to claim 1, wherein the second semiconductor structure includes a peripheral semiconductor pin contacting an upper surface of the first insulating layer in the peripheral circuit region,
wherein the peripheral circuit transistor includes a peripheral gate pattern surrounding an upper surface and a sidewall of the peripheral semiconductor fin, and a first peripheral source/drain region and a second peripheral source/drain region formed in the peripheral semiconductor fin at both sides of the peripheral gate pattern, respectively, and
wherein a depth of each of the first and second peripheral source/drain regions is equal to a thickness of the peripheral semiconductor fin.

6. The semiconductor device according to claim 1, wherein a lower surface of the first cell source/drain region contacts the first conductor.

7. The semiconductor device according to claim 1, wherein the first conductor further passes through the first cell source/drain region and has a sidewall that contacts the first cell source/drain region.

8. The semiconductor device according to claim 1, wherein the second semiconductor structure further includes:
a second insulating layer covering the cell transistor and the peripheral circuit transistor; and
second to sixth conductors passing through the second insulating layer, and respectively connected to a gate electrode of the cell transistor, a second cell source/drain region of the cell transistor, a first peripheral source/drain region of the peripheral circuit transistor, a gate electrode of the peripheral circuit transistor, and a second peripheral source/drain region of the peripheral circuit transistor.

9. The semiconductor device according to claim 1, the first semiconductor structure further includes a decoupling capacitor disposed in the first insulating layer in the peripheral circuit region.

10. The semiconductor device according to claim 9, wherein the second semiconductor structure further includes:
a second insulating layer covering the cell transistor and the peripheral circuit transistor;
second to sixth conductors passing through the second insulating layer, and respectively connected to a gate electrode of the cell transistor, a second cell source/drain region of the cell transistor, a first peripheral source/drain region of the peripheral circuit transistor, a gate electrode of the peripheral circuit transistor, and a second peripheral source/drain region of the peripheral circuit transistor; and
a seventh conductor passing through the second insulating layer and the first insulating layer, and connected to an electrode of the decoupling capacitor.

11. The semiconductor device according to claim 1, wherein the second semiconductor structure includes a semiconductor substrate contacting an upper surface of the first insulating layer,
wherein the cell transistor includes a cell gate pattern disposed over the semiconductor substrate, and the first cell source/drain region and a second cell source/drain region formed in the semiconductor substrate at both sides of the cell gate pattern, respectively, and
wherein the peripheral circuit transistor includes a peripheral gate pattern disposed over the semiconductor substrate, and a first peripheral source/drain region and a second peripheral source/drain region formed in the semiconductor substrate at both sides of the peripheral gate pattern, respectively.

12. The semiconductor device according to claim 1, wherein the second semiconductor structure includes a cell semiconductor pin contacting an upper surface of the first insulating layer in the cell region, and a semiconductor substrate contacting the upper surface of the first insulating layer in the peripheral circuit region,
wherein the cell transistor includes a cell gate pattern surrounding an upper surface and a sidewall of the cell semiconductor fin, and the first cell source/drain region and a second cell source/drain region formed in the cell semiconductor fin at both sides of the cell gate pattern, respectively, and
wherein the peripheral circuit transistor includes a peripheral gate pattern disposed over the semiconductor substrate, and a first peripheral source/drain region and a second peripheral source/drain region formed in the semiconductor substrate at both sides of the peripheral gate pattern, respectively.

13. The semiconductor device according to claim 1, wherein the second semiconductor structure includes a cell semiconductor pin contacting an upper surface of the first insulating layer in the cell region, and a peripheral semiconductor pin contacting the upper surface of the first insulating layer in the peripheral circuit region,
wherein the cell transistor includes a cell gate pattern surrounding an upper surface and a sidewall of the cell semiconductor fin, and the first cell source/drain region and a second cell source/drain region formed in the cell semiconductor fin at both sides of the cell gate pattern, respectively, and
wherein the peripheral circuit transistor includes a peripheral gate pattern surrounding an upper surface and a sidewall of the peripheral semiconductor fin, and a first peripheral source/drain region and a second peripheral source/drain region formed in the peripheral semiconductor fin at both sides of the peripheral gate pattern, respectively.

14. The semiconductor device according to claim 13, wherein at least one of a thickness and a width of the cell semiconductor fin and at least one of a thickness and a width of the peripheral semiconductor fin are different from each other.

15. A method for fabricating a semiconductor device, the method comprising:
providing a first semiconductor structure that includes a cell region and a peripheral circuit region, a cell capacitor disposed in the cell region, and a first insulating layer disposed in the cell region and the peripheral circuit region to cover the cell capacitor;
bonding a semiconductor substrate to an upper surface of the first insulating layer;
forming a cell transistor in the cell region and forming a peripheral circuit transistor in the peripheral circuit region, using the semiconductor substrate; and
forming a conductor that passes through the first insulating layer and connects a first source/drain region of the cell transistor with an electrode of the cell capacitor.

16. The method according to claim 15, wherein forming the conductor is performed before the bonding of the semiconductor substrate, and
the semiconductor substrate contacts an upper surface of the conductor.

17. The method according to claim 15, wherein forming the conductor is performed so that the conductor further passes through the first source/drain region of the cell transistor, after forming the cell transistor.

18. The method according to claim 15, wherein forming the cell transistor includes forming a source/drain region by doping impurities into the semiconductor substrate of the cell region or a semiconductor fin formed by selective etching the semiconductor substrate of the cell region, and
a depth of the source/drain region is equal to a thickness of the semiconductor substrate or the semiconductor fin.

19. The method according to claim 15, wherein forming the peripheral circuit transistor includes forming a source/drain region by doping impurities into the semiconductor substrate of the peripheral circuit region or a semiconductor fin formed by selective etching the semiconductor substrate of the peripheral circuit region, and
a depth of the source/drain region is equal to a thickness of the semiconductor substrate or the semiconductor fin.

20. The method according to claim 15, wherein the cell transistor is formed in a state in which a first mask pattern covering the semiconductor substrate in the peripheral circuit region is formed, and
the peripheral circuit transistor is formed in a state in which a second mask pattern covering the semiconductor substrate in the cell region is formed.

21. The method according to claim 15, wherein forming the cell transistor includes forming a cell gate pattern over the semiconductor substrate, and forming a first cell source/drain region and a second cell source/drain region in the semiconductor substrate at both sides of the cell gate pattern, respectively, and
wherein forming the peripheral circuit transistor includes forming a peripheral gate pattern over the semiconductor substrate, and forming a first peripheral source/drain region and a second peripheral source/drain region in the semiconductor substrate at both sides of the peripheral gate pattern, respectively.

22. The method according to claim 15, wherein forming the cell transistor includes forming a cell semiconductor fin by etching the semiconductor substrate of the cell region, forming a cell gate pattern along an upper surface and a sidewall of the cell semiconductor fin, and forming a first cell source/drain region and a second cell source/drain region in the cell semiconductor fin at both sides of the cell gate pattern, respectively, in a state in which the peripheral circuit region is covered, and
wherein forming the peripheral circuit transistor includes forming a peripheral gate pattern over the semiconductor substrate in the peripheral circuit region, and forming a first peripheral source/drain region and a second peripheral source/drain region in the semiconductor substrate at both sides of the peripheral gate pattern, respectively, in a state in which the cell region is covered.

23. The method according to claim 15, wherein forming the cell transistor includes forming a cell semiconductor fin by etching the semiconductor substrate of the cell region, forming a cell gate pattern along an upper surface and a sidewall of the cell semiconductor fin, and forming a first cell source/drain region and a second cell source/drain region in the cell semiconductor fin at both sides of the cell gate pattern, respectively, in a state in which the peripheral circuit region is covered, and
wherein forming the peripheral circuit transistor includes forming a peripheral semiconductor fin by etching the semiconductor substrate of the peripheral circuit region, forming a peripheral gate pattern along an upper surface and a sidewall of the peripheral semiconductor fin, and forming a first peripheral source/drain region and a second peripheral source/drain region in the peripheral semiconductor fin at both sides of the peripheral gate pattern, respectively, in a state in which the cell region is covered.

24. The method according to claim 15, wherein the first semiconductor structure further includes a decoupling capacitor disposed in the first insulating layer in the peripheral circuit region.
